(19) United States
(12) Patent Application Publication
(10) Pub. No.: US 2012/0235127 A1
(43) Pub. Date: Sep. 20, 2012

(54) ORGANIC LIGHT-EMITTING DIODE, DISPLAY AND ILLUMINATING DEVICE

(76) Inventors: Isao TAKASU, Tokyo (JP); Keiji Sugi, Fujisawa-shi (JP); Tomoaki Sawabe, Tokyo (JP); Akio Amano, Machida-shi (JP); Jiro Yoshida, Yokohama-shi (JP); Tomio Ono, Yokohama-shi (JP); Shintaro Enomoto, Yokohama-shi (JP)

(21) Appl. No.: 13/422,337

(22) Filed: Mar. 16, 2012

(30) Foreign Application Priority Data
Mar. 17, 2011 (JP) 2011-059917

(51) Int. Cl. H01L 51/54

(52) U.S. Cl. 257/40; 257/E51.026

(57) ABSTRACT

According to one embodiment, there is provided an organic light-emitting diode including an anode and a cathode which are arranged apart from each other, an emissive layer arranged between the anode and the cathode including a blue emissive layer located at the anode side and a green and red emissive layer located at the cathode side, the blue emissive layer containing a host material and a blue fluorescent dopant, and the green and red emissive layer containing a host material and a green phosphorescent dopant and/or a red phosphorescent dopant.

### CROSS-REFERENCE TO RELATED APPLICATIONS

This application is based upon and claims the benefit of priority from prior Japanese Patent Application No. 2011-059917, filed Mar. 17, 2011, the entire contents of which are incorporated herein by reference.

### FIELD

Embodiments described herein relate generally to an organic light-emitting diode, a display and an illuminating device.

### BACKGROUND

Application development of a white organic light-emitting diode to backlight of an illuminating device and a display has been proceeded. When a fluorescent material is used as an emitting dopant, emission only from an excited singlet (hereinafter referred to as S1) occurs, and thus only 25% internal quantum efficiency can be expected in spin statistics. On the other hand, when a phosphorescent dopant such as an iridium complex is used, emission from an excited triplet (hereinafter referred to as T1) occurs, and thus 100% internal quantum efficiency can be expected. Therefore, application of a phosphorescent dopant to a white organic light-emitting diode has been expected. However, many of the phosphorescent materials showing blue emission, which are essential to form white light, have a short diode lifetime. Thus, there still remains a problem on practical side. Then, attempts to produce a white organic light-emitting diode with high efficiency have been made by using a blue fluorescent dopant which has an emission lifetime longer than that of a blue phosphorescent dopant.

In the white organic light-emitting diode using a conventional blue fluorescent dopant, it has been necessary to use the blue fluorescent dopant with a high T1 energy. However, the blue fluorescent dopant with the high T1 energy is very few in number. Accordingly, there is a need for a diode configuration in which the blue fluorescent dopant can be used regardless of the T1 energy.

### BRIEF DESCRIPTION OF THE DRAWINGS

FIG. 1 is a cross-sectional view of an organic light-emitting diode of an embodiment;

FIG. 2 is a conceptual diagram showing an example of an emissive layer in a conventional diode;

FIG. 3 is a view showing the fluorescence spectrum obtained by measuring a mixed film including a hole transport material and OXD-7;

FIG. 4 is a view showing the fluorescence spectrum obtained by measuring a single-component film including each component contained in the mixed film shown in FIG. 3;

FIG. 5 is a view showing the fluorescence spectrum obtained by measuring a mixed film including a hole transport material and OXD-7 and a single component film of OXD-7;

FIG. 6 is a view showing an energy relationship between excitons and OXD-7;

FIGS. 7A and 7B are a conceptual diagrams showing an emissive layer in an organic light-emitting diode according to an embodiment;

FIGS. 8A and 8B are views showing a HOMO-LUMO relationship between emitting dopants and host materials in an organic light-emitting diode according to an embodiment;

FIG. 9 is a view showing a first modification of an organic light-emitting diode according to an embodiment;

FIG. 10 is a view showing a second modification of an organic light-emitting diode according to an embodiment;

FIG. 11 is a view showing a third modification of an organic light-emitting diode according to an embodiment;

FIG. 12 is a circuit diagram showing a display of an embodiment;

FIG. 13 is a cross-sectional view showing a lighting device of an embodiment;

FIG. 14 is a view showing the electroluminescence spectrum of an organic light-emitting diode according to Example 1; and

FIG. 15 is a view showing the external quantum efficiency of an organic light-emitting diode according to Example 1.

### DETAILED DESCRIPTION

In general, according to one embodiment, there is provided an organic light-emitting diode including an anode and a cathode which are arranged apart from each other; an emissive layer arranged between the anode and the cathode including a blue emissive layer located at the anode side and a green and red emissive layer located at the cathode side, the blue emissive layer containing a host material and a blue fluorescent dopant, and the green and red emissive layer containing a host material and a green phosphorescent dopant and/or a red phosphorescent dopant. The excited triplet energy of the blue fluorescent dopant is lower than at least one of the excited triplet energy of the green phosphorescent dopant and the red phosphorescent dopant. The excited triplet energy of the host material included in the blue emissive layer is higher than that of the host material contained in the green and red emissive layer. The energy level of HOMO of the host material contained in the blue emissive layer is shallower than that of HOMO of the host material contained in the green and red emissive layer. The energy level of LUMO of the host material contained in the blue emissive layer is shallower than that of LUMO of the host material contained in the green and red emissive layer. Excitons are generated at the interface between the blue emissive layer and the green and red emissive layer.

Embodiments of the present invention are explained below in reference to the drawings.

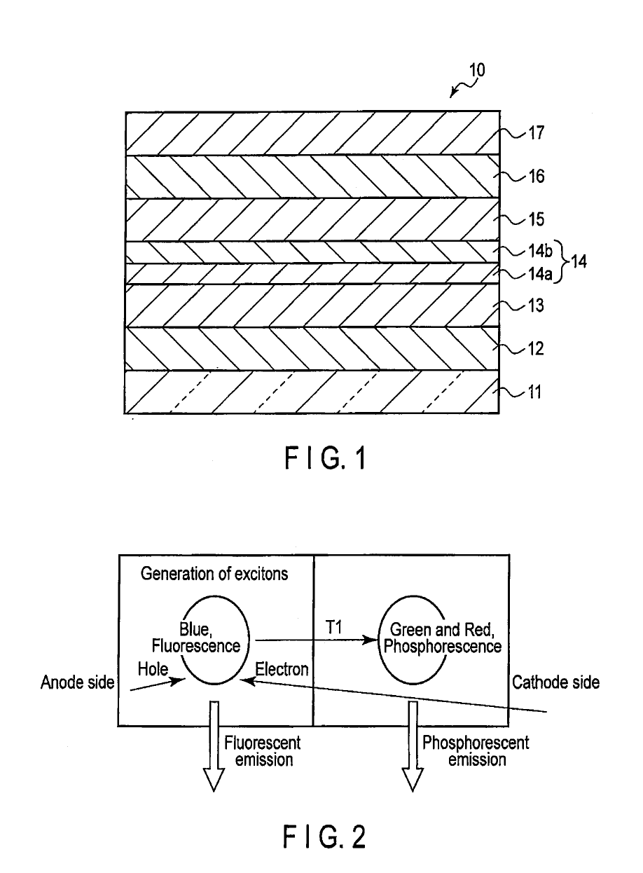

FIG. 1 is a cross-sectional view of the organic light-emitting diode of an embodiment.

In the organic light-emitting diode 10, an anode 12, hole transport layer 13, emissive layer 14, electron transport layer 15, electron injection layer 16 and cathode 17 are formed in sequence on a substrate 11. The hole transport layer 13, electron transport layer 15 and electron injection layer 16 are formed if necessary.

The emissive layer 14 includes a blue emissive layer 14a that is located at the anode side and a green and red emissive layer 14b that is located at the cathode side.

The emissive layer 14 has a configuration in which a luminescent metal complex is doped in a host material composed of organic materials. The blue emissive layer 14a has a configuration in which the blue fluorescent dopant is doped in the host material. The green and red emissive layer 14b has a configuration in which either the green phosphorescent dopant or the red phosphorescent dopant or both the green phosphorescent dopant and the red phosphorescent dopant are doped in the host material. The blue emissive layer 14a contains a hole transport host material. The green and red emissive layer 14b contains an electron transport host material or a bipolar host material. The term “bipolar host material” means a host material which possesses both hole and electron transport properties. Excitons generated by collision of the electron and the hole are generated at the interface between the blue emissive layer 14a and the green and red emissive layer 14b. Emission is obtained by using the energy released from the excitons. The exciton may be an exciplex produced by the formation of a complex by the hole transport host material and the electron transport host material at an excited state.

The circumstances leading to the configuration of the emissive layer will be described hereinafter.

FIG. 2 is a conceptual diagram showing an example of an emissive layer as a conventional diode.

The emissive layer shown in FIG. 2 is divided into two layers at the anode and cathode sides. The blue fluorescent dopant is included in the anode side and the green phosphorescent dopant and/or the red phosphorescent dopant are included in the cathode side. First, an electron and a hole are transferred to the emissive layer at the anode side to generate excitons, resulting in excitation of the blue emitting dopant. As a result, the blue fluorescence which is an emission from an excited singlet (S1) is obtained. Since the fluorescent dopant cannot utilize the excited triplet (T1) energy, the blue emitting dopant radiates the T1 energy. The green and red emitting dopant included in the emissive layer at the cathode side absorbs the T1 energy radiated and thus green and red phosphorescence is obtained.

According to such a conventional configuration, there is no thermal inactivation of the T1 energy in the blue emitting dopant and thus the internal quantum efficiency becomes 100% in principle. In order to allow the green and red emitting dopant to be excited by the T1 energy radiated from the blue emitting dopant, the T1 energy of the blue emitting dopant needs to be higher than that of the green and red emitting dopant. However, few blue fluorescent dopants have the high T1 energy which satisfies such a condition. When the T1 energy of the blue fluorescent dopant is increased by molecular design, the S1 energy is simultaneously increased. Thus, a problem that the blue fluorescence becomes ultraviolet rays is caused.

The present inventors have found out the configuration of the emissive layer which can solve such a problem in the following manner.

First, a mixed film including various types of hole transport materials and 1,3-bis(2-(4-tertiary-buthylphenyl)-1,3,4-oxadiazol-5-yl)benzene (hereinafter referred to as OXD-7) which is an electron transport material is produced and then the fluorescent and phosphorescent spectra of the film were measured. The fluorescent and phosphorescent spectra of the single component film including each component contained in the mixed film are measured.

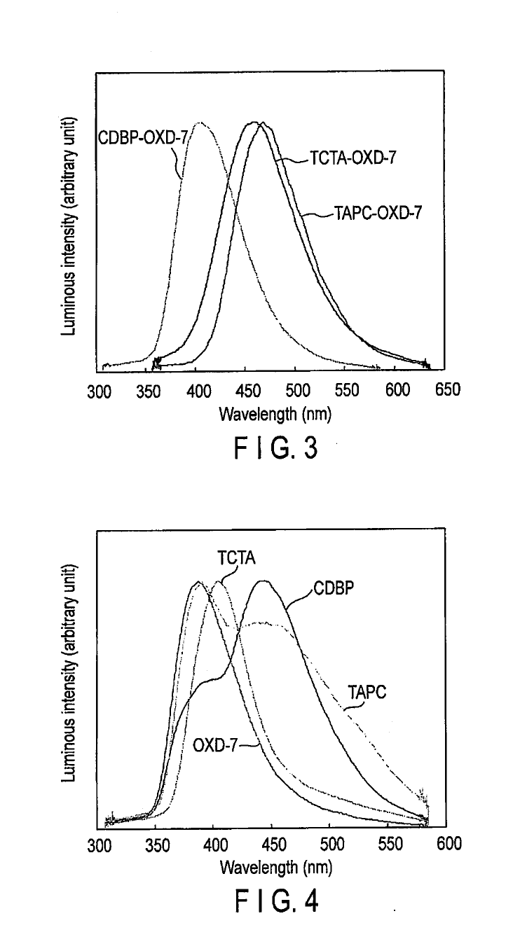

FIG. 3 is a view showing the fluorescence spectrum obtained by measuring a mixed film including a hole transport material and OXD-7. FIG. 4 is a view showing the fluorescence spectrum obtained by measuring a single-component film including each component contained in the mixed film shown in FIG. 3.

When FIG. 3 is compared with FIG. 4, all the spectra of the mixed film shown in FIG. 3 show light-emitting wavelengths different from the spectra of the single component film shown in FIG. 4. From this fact, it is found that the emission from the exciplex is obtained in the mixed film of a hole transport material and OXD-7.

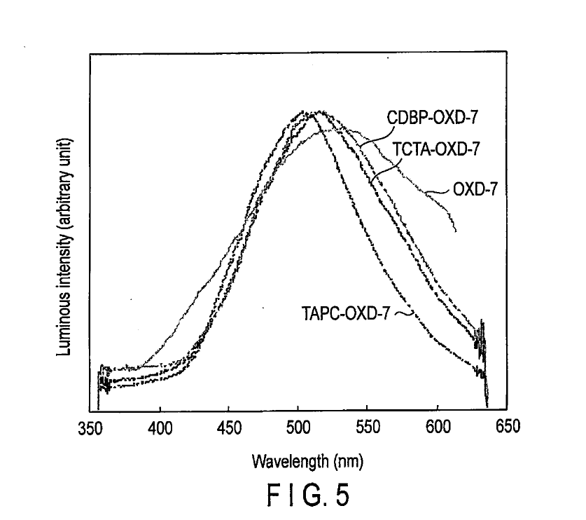

On the other hand, when the phosphorescence spectrum of the mixed film of a hole transport material and OXD-7 is measured, the light-emitting wavelength of each mixed film is nearly identical to the light-emitting wavelength of OXD-7 alone. The results are shown in FIG. 5. As shown in Table 1 below, the phosphorescent emission lifetime of the single component film of OXD-7 is nearly identical to the phosphorescent emission lifetime of the mixed film of a hole transport material and OXD-7.

TABLE 1

| | Phosphorescent emission |
|---|---|
| | Lifetime (ms) |
| OXD-7 | 442 |
| TCTA-OXD-7 | 434 |
| TAPC-OXD-7 | 463 |
| CDBP-OXD-7 | 465 |

From these results, it is found that the phosphorescence obtained from the mixed film is derived from OXD-7. In other words, the T1 energy released from excitons are selectively transferred to OXD-7. As the result of this test, the present inventors have found out that the T1 energy released from excitons can be selectively transferred to a certain material by using a material which satisfies a predetermined requirement. Therefore, if the above fact is utilized, the T1 energy can selectively be transferred to the electron transport host material in the emissive layer containing the electron transport material like OXD-7 and the hole transport material which maintain a carrier balance with the electron transport host material.

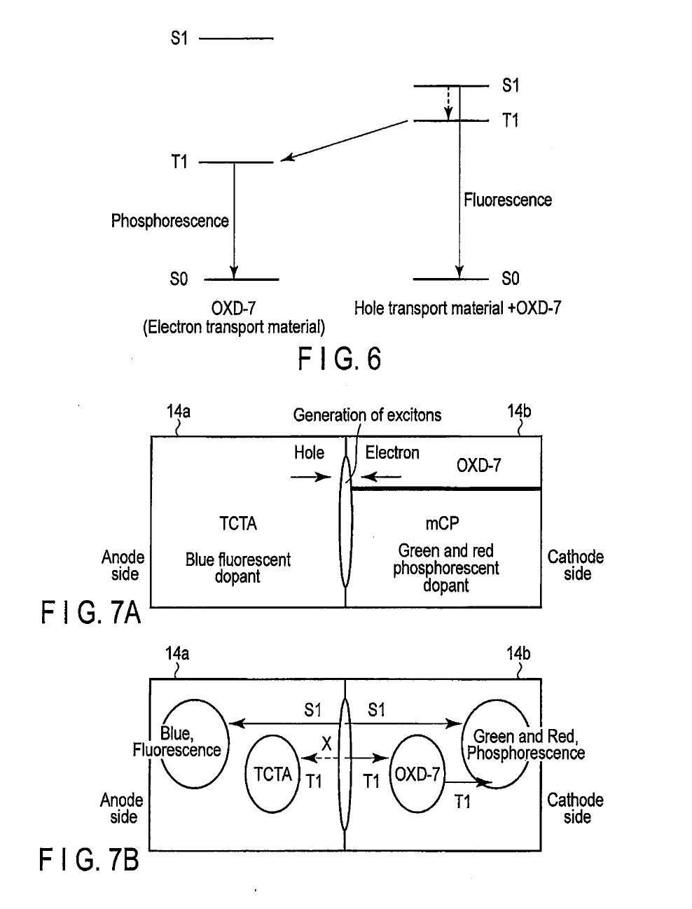

This state can be indicated as shown in FIG. 6. FIG. 6 is a view showing an energy state in a mixed film including a hole transport material and OXD-7. FIG. 6 shows that when the mixed film is excited, the T1 energy transfers to OXD-7 and the phosphorescence is obtained from OXD-7. On the other hand, the fluorescence by an S1 energy is obtained from both of the hole transport material and OXD-7.

The present inventors have found out the above fact and devised the configuration of the emissive layer as shown in FIGS. 7A and 7B.

FIG. 7A is a view showing the transfer of the electron and hole in the emissive layer in the organic light-emitting diode according to the embodiment. The blue emissive layer 14a at the anode side contains the hole transport host material (TCTA in the drawing) and the blue fluorescent dopant. On the other hand, the green and red emissive layer 14b at the cathode side contains the electron transport or bipolar host materials (OXD-7 in the drawing) and either the green phosphorescent dopant or the red phosphorescent dopant or both the green phosphorescent dopant and the red phosphorescent dopant. In FIG. 7, the case where both the green phosphorescent dopant and the red phosphorescent dopant are included are illustrated. In order to keep the carrier balance between the hole and electron in the emissive layer 14, the green and red emissive layer 14b may further contain a hole transport material (mCP in the drawing). The hole injected into the blue emissive layer 14a from the anode side and the electron injected into the green and red emissive layer 14b from the cathode side transfer to the interface between the blue emissive layer 14a and the green and red emissive layer 14b. As a result, excitons are generated at the interface.

FIG. 7B is a view showing the transfer of energy in the emissive layer in the organic light-emitting diode according to the embodiment. The excited singlet (S1) energy released from excitons generated at the interface between the blue emissive layer 14a and the green and red emissive layer 14b transfers to both the blue emissive layer 14a and the green and red emissive layer 14b. On the other hand, as described above, the T1 energy released from excitons can selectively be transferred to a certain material by using a material which satisfies a predetermined requirement. Taking advantage of the above fact, the host material is selected so as to transfer the T1 energy only to the green and red emissive layer 14b. For example, as shown in FIG. 7B, when TCTA is used as the host material included in the blue emissive layer 14a and OXD-7 is used as the host material included in the green and red emissive layer 14b, the T1 energy released from excitons is selectively transferred to OXD-7. As a result, the blue fluorescent dopant receives the S1 energy, the green phosphorescent dopant and the red phosphorescent dopant receive the S1 energy and the T1 energy, and each dopant emits fluorescence and phosphorescence.

As shown in FIG. 7B, in order to selectively transfer the T1 energy released from excitons to the green and red emissive layer 14b, it is necessary that the T1 energy of the host material included in the blue emissive layer 14b is higher than that of the host material included in the green and red emissive layer 14b. In order to transfer the T1 energy released from the host material included in the green and red emissive layer 14b to the green and red emitting dopant efficiently, it is necessary that the T1 energy of the host material included in the green and red emissive layer 14b is higher than that of the green and red emitting dopant.

According to the above mechanisms, the green phosphorescent dopant and the red phosphorescent dopant utilize the T1 energy released not from the blue emitting dopant, but excitons, and thus it is unnecessary to use the blue emitting dopant with a high T1 energy. That is, even if the T1 energy of the blue emitting dopant is lower than that of the green and red emitting dopant, no problem is caused. Thus, the blue fluorescent dopant can be used regardless of the T1 energy, which expands the range of choices for the material. Further, it is unnecessary to make the T1 energy of the blue fluorescent dopant higher by molecular design and thus the problem that the blue fluorescence becomes ultraviolet rays is not caused. According to the above mechanism, the blue fluorescent dopant does not receive T1 energy. Therefore, an organic light-emitting diode which has no thermal inactivation of the T1 energy in the blue emitting dopant and has an internal quantum efficiency of 100% in principle is obtained.

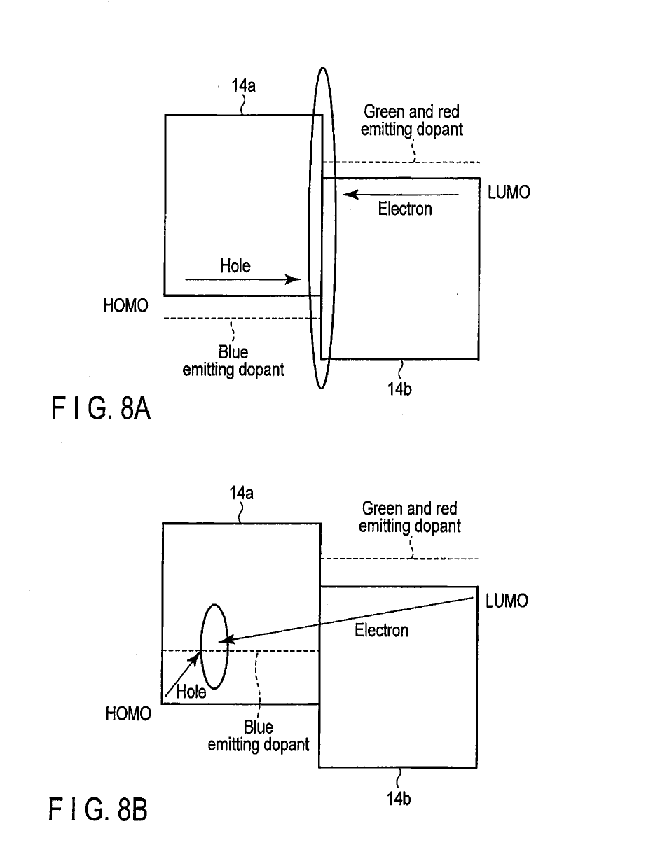

FIGS. 8A and 8B are a view showing a HOMO-LUMO relationship between emitting dopants and host materials in an organic light-emitting diode according to an embodiment. FIG. 8A shows a preferable example where excitons are efficiently produced at the interface between the blue emissive layer and the green and red emissive layer.

In order to generate excitons at the interface between the blue emissive layer 14a and the green and red emissive layer 14b, as shown in FIG. 8A, the energy level of Highest Occupied Morecular Orbital (hereinafter referred to as HOMO) of the host material included in a blue emissive layer 14a is shallower than that of the host material included in the green and red emissive layer 14b. Further, the energy level of Lowest Unoccupied Molecular Orbital (hereinafter referred to as LUMO) of the host material included in the blue emissive layer 14a is shallower than that of the host material included in the green and red emissive layer 14b. The use of the host material with such a energy relationship allows a barrier against the electron and hole to be formed between the hole transport host material and the electron transport host material. As a result, the electron and hole are accumulated at the interface between the blue emissive layer 14a and the green and red emissive layer 14b, and then excitons are generated.

In order to efficiently generate excitons at the interface between the blue emissive layer 14a and the green and red emissive layer 14b, it is preferable that the hole and electrons injected to the diode are hard to be trapped by the emitting dopant. If a career is trapped by the emitting dopant, generation of excitons preferentially occurs on the emitting dopant. Thus, excitons are hard to be generated at the interface of the blue emissive layer 14a and the green and red emissive layer 14b, and, it is hard to have a mechanism in which the emitting dopant receives energy from the excitons at the interface and emits light.

In order to prevent the career from being trapped on the emitting dopant, the energy level of HOMO of the host material in the blue emissive layer 14a is preferably the same as or shallower than that of HOMO of the blue fluorescent dopant. In the green and red emissive layer 14b, the energy level of LUMO of the host material is preferably the same as or deeper than those of LUMO of the green phosphorescent dopant and the red phosphorescent dopant.

According to FIG. 8A, the energy level of HOMO of the host material in the blue emissive layer 14a is shallower than that of HOMO of the blue fluorescent dopant, and thus the hole is smoothly transferred to the interface between the blue emissive layer 14a and the green and red emissive layer 14b. In the green and red emissive layer 14b, the energy level of LUMO of the host material is deeper than that of LUMO of the green phosphorescent dopant and the red phosphorescent dopant and thus electrons are smoothly transferred to the interface between the blue emissive layer 14a and the green and red emissive layer 14b.

FIG. 8B shows an example where the hole and electrons are trapped by the emitting dopant and excitons are easily created at sites other than the interface between the blue emissive layer 14a and the green and red emissive layer 14b. In the blue emissive layer 14a, the energy level of HOMO of the blue emitting dopant is shallower than that of HOMO of the host material and thus the hole is trapped on the emitting dopant.

An emission component of excitons which are generated at the interface between the blue emissive layer 14a and the green and red emissive layer 14b has an emission lifetime longer than the emission lifetime of either the host material included in the blue emissive layer 14a or the host material included in the green and red emissive layer 14b. In many cases, the long emission lifetime component is composed of a component with a wavelength longer than emission wavelengths of either the host material included in the blue emissive layer 14a or the host material included in the green and red emissive layer 14b.

Usable examples of the blue fluorescent dopant include 1-4-di-[4-(N,N-diphenyl)amino]styryl-benzene (hereinafter referred to as DSA-Ph) and 4,4′-bis(9-ethyl-3-carbazovinylene)-1,1′-biphenyl (hereinafter referred to as BCzVBi). Usable examples of the green phosphorescent dopant include tris(2-phenylpyridine)iridium (III) (hereinafter referred to as Ir(ppy)₃) and tris(2-(p-tolyl)pyridine)iridium (III) (hereinafter referred to as Ir(mppy)₃). Usable examples of the red phosphorescencent dopant include bis(2-methyldibenzo-[f,h]quinoxaline)(acetylacetonato)iridium (III) (hereinafter referred to as Ir(MDQ)₂(acac)) and tris(1-phenylisoquinoline) iridium (III) (hereinafter referred to as Ir(piq)₃).

Examples of the hole transport host material included in the blue emissive layer 14a include di-[4-(N,N-ditolylamino)phenyl]cyclohexane (hereinafter referred to as TAPC) and 4,4′,4″-tris(9-carbazolyl)-triphenylamine (hereinafter referred to as TCTA). Examples of the electron transport host material included in the green and red emissive layer 14b include OXD-7,4,7-diphenyl-1,10-phenanthroline (hereinafter referred to as Bphen), and bis(2-methyl-8-quinolinolate)-4-(phenylphenolate)aluminium (hereinafter referred to as BAlq). Examples of the bipolar host material contained in the green and red emissive layer include 4,4′-bis(9-dicarbazolyl)-2,2′-biphenyl (hereinafter referred to as CBP).

Usable examples of the hole transport material which is contained in the green and red emissive layer 14b to maintain a carrier balance include 1,3-bis(carbazole-9-yl)benzene (hereinafter referred to as mCP), di-[4-(N,N-ditolylamino)phenyl]cyclohexane (hereinafter referred to as TAPC) and 4,4′,4″-tris(9-carbazolyl)-triphenylamine (hereinafter referred to as TCTA). When a host material with strong electron transport properties is used, the carrier balance between the hole and electrons in the emissive layer 14 is not kept, which causes a problem of a decrease in emission efficiency. Therefore, when the electron transport host material is used as a host material in the green and red emissive layer 14b, it is preferable to take into consideration adding the hole transport material.

The method of forming a blue emissive layer and a green and red emissive layer 14b is not particularly limited as long as it is a method capable of forming a thin film. For example, a spin coat method, a vacuum deposition method or the like can be used. A solution containing the emitting dopant and the host material is applied to have a desired thickness, followed by heating and drying with a hot plate or the like. The solution to be applied may be filtrated with a filter in advance.

The thickness of the blue emissive layer 14a is preferably from 10 to 100 nm and the thickness of the green and red emissive layer 14b is preferably from 10 to 100 nm. The ratio of the electron transport material, the hole transport material, and the emitting dopants in the emissive layer 14 is arbitrary unless the effect of the present embodiment is impaired.

Other members of the organic light-emitting diode according to the embodiment will be described in detail with reference to FIG. 1.

The substrate 11 is a member for supporting other members. The substrate 11 is preferably one which is not modified by heat or organic solvents. A material of the substrate 11 includes, for example, an inorganic material such as alkali-free glass and quartz glass; plastic such as polyethylene, polyethylene terephthalate (PET), polyethylene naphthalate (PEN), polyimide, polyamide, polyamide-imide, liquid crystal polymer, and cycloolefin polymer; polymer film; and metal substrate such as stainless steel (SUS) and silicon. In order to obtain light emission, a transparent substrate consisting of glass, synthesized resin, and the like is preferably used. Shape, structure, size, and the like of the substrate 11 are not particularly limited, and can be appropriately selected in accordance with application, purpose, and the like. The thickness of the substrate 11 is not particularly limited as long as it has sufficient strength for supporting other members.

The anode 12 is formed on the substrate 11. The anode 12 injects holes into the hole transport layer 13 or the emissive layer 14. A material of the anode 12 is not particularly limited as long as it exhibits conductivity. Generally, a transparent or semitransparent material having conductivity is deposited by vacuum evaporation, sputtering, ion plating, plating, and coating methods, and the like. For example, a metal oxide film and semitransparent metallic thin film exhibiting conductivity may be used as the anode 12. Specifically, a film prepared by using conductive glass consisting of indium oxide, zinc oxide, tin oxide, indium tin oxide (ITO) which is a complex thereof, fluorine doped tin oxide (FTO), indium zinc oxide, and the like (NESA etc.); gold; platinum; silver; copper; and the like are used. In particular, it is preferably a transparent electrode consisting of ITO. As an electrode material, organic conductive polymer such as polyaniline, the derivatives thereof, polythiophene, the derivatives thereof, and the like may be used. When ITO is used as the anode 12, the thickness thereof is preferably 30-300 nm. If the thickness is thinner than 30 nm, the conductivity is decreased and the resistance is increased, resulting in reducing the luminous efficiency. If it is thicker than 300 nm, ITO loses flexibility and is cracked when it is under stress. The anode 12 may be a single layer or stacked layers each composed of materials having various work functions.

The hole transport layer 13 is optionally arranged between the anode 12 and emissive layer 14. The hole transport layer 13 receives holes from the anode 12 and transports them to the emissive layer side. As a material of the hole transport layer 13, for example, polythiophene type polymer such as a conductive ink, poly(ethylenedioxythiophene):polystyrene sulfonate (hereinafter, referred to as PEDOT:PSS) can be used, but is not limited thereto. A method for forming the hole transport layer 13 is not particularly limited as long as it is a method which can form a thin film, and may be, for example, a spin coating method. After applying a solution of hole transport layer 13 in a desired film thickness, it is heated and dried with a hotplate and the like. The solution to be applied may be filtrated with a filter in advance.

The electron transport layer 15 is optionally formed on the emissive layer 14. The electron transport layer 15 receives electrons from the electron injection layer 16 and transports them to the emissive layer side. As a material of the electron transport layer 15 is, for example, tris[3-(3-pyridyl)-mesityl]borane (hereinafter, referred to as 3TPYMB), tris(8-hydroxyquinolinato)aluminum (hereinafter, referred to as Alq₃), and basophenanthroline (BPhen), but is not limited thereto. The electron transport layer 15 is formed by vacuum evaporation method, a coating method or the like.

The electron injection layer 16 is optionally formed on the electron transport layer 15. The electron injection layer 16 receives electrons from the cathode 17 and transports them to the electron transport layer 15 or emissive layer 14. A material of the electron injection layer 16 is, for example, CsF, LiF, and the like, but is not limited thereto. The electron injection layer 16 is formed by vacuum evaporation method, a coating method or the like.

The cathode 17 is formed on the emissive layer 14 (or the electron transport layer 15 or the electron injection layer 16). The cathode 17 injects electrons into the emissive layer 14 (or the electron transport layer 15 or the electron injection layer 16). Generally, a transparent or semitransparent material having conductivity is deposited by vacuum evaporation, sputtering, ion plating, plating, coating methods, and the like. Materials for the cathode include a metal oxide film and semitransparent metallic thin film exhibiting conductivity. When the anode 12 is formed with use of a material having high work function, a material having low work function is preferably used as the cathode 17. A material having low work function includes, for example, alkali metal and alkali earth metal. Specifically, it is Li, In, Al, Ca, Mg, Na, K, Yb, Cs, and the like.

The cathode 17 may be a single layer or stacked layers each composed of materials having various work functions. Further, it may be an alloy of two or more metals. Examples of the alloy include a lithium-aluminum alloy, lithium-magnesium alloy, lithium-indium alloy, magnesium-silver alloy, magnesium-indium alloy, magnesium-aluminum alloy, indium-silver alloy, and calcium-aluminum alloy.

The thickness of the cathode 17 is preferably 10-150 nm. When the thickness is thinner than the aforementioned range, the resistance is excessively high. When the film thickness is thicker, long period of time is required for deposition of the cathode 17, resulting in deterioration of the performance due to damage to the adjacent layers.

Explained above is an organic light-emitting diode in which an anode is formed on a substrate and a cathode is arranged on the opposite side to the substrate, but the substrate may be arranged on the cathode side.

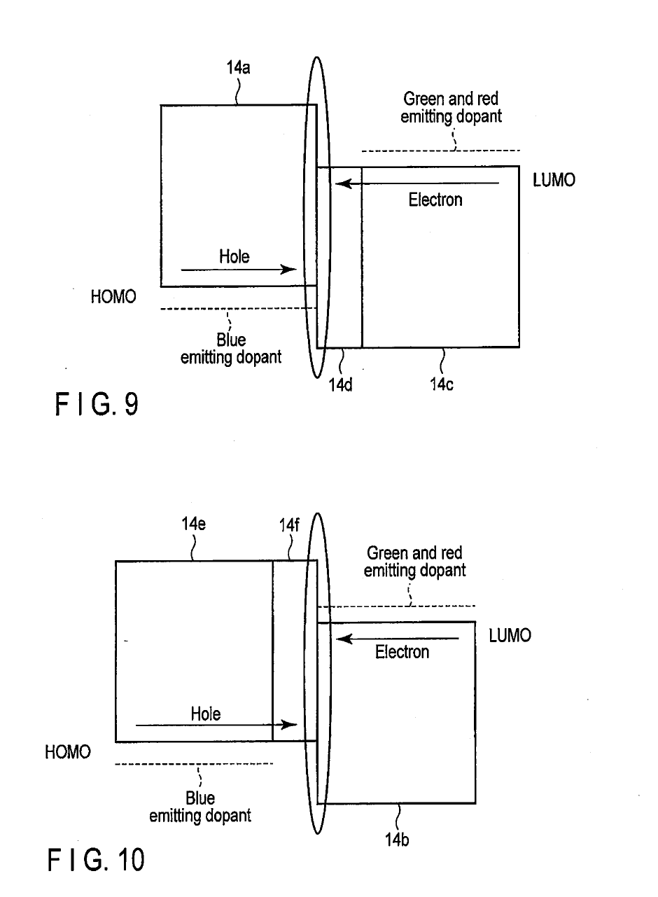

Subsequently, modifications of the organic light-emitting diode according to the embodiment will be described. FIG. 9 is a view showing a first modification of an organic light-emitting diode according to an embodiment.

In the first modification, the green and red emissive layer 14b includes a region 14c at the cathode side which contains the electron transport host material, the green phosphorescent dopant, and the red phosphorescent dopant and a region 14 d at the anode side which contains the electron transport host material and does not contain the emitting dopant. In the region 14c, either the green phosphorescent dopant or the red phosphorescent dopant or both the green phosphorescent dopant and the red phosphorescent dopant may be contained. It is preferable that the electron transport host material included in the region 14c at the cathode side is identical to that included in the region 14d at the anode side. The material included in the region 14c at the cathode side and the method of forming thereof are the same as those of the green and red emissive layer 14b shown in the above embodiment. The region 14d at the anode side can be formed by changing the material in the same manner as that of the region 14c at the cathode side. The blue emissive layer 14a is as described in the embodiment.

FIG. 10 is a view showing a second modification of an organic light-emitting diode according to an embodiment.

In the second modification, the blue emissive layer 14a includes a region 14e at the anode side which contains the hole transport host material and the blue emitting dopant and a region 14f at the cathode side which contains the hole transport host material and does not contain the emitting dopant. It is preferable that the hole transport host material included in the region 14e at the anode side is identical to that included in the region 14f at the cathode side. The material included in the region 14e at the anode side and the method of forming thereof are the same as those of the blue emissive layer shown in the above embodiment. The region 14f at the cathode side can be formed by changing the material in the same manner as that of the region 14e at the anode side. The green and red emissive layer 14b is as described in the above embodiment.

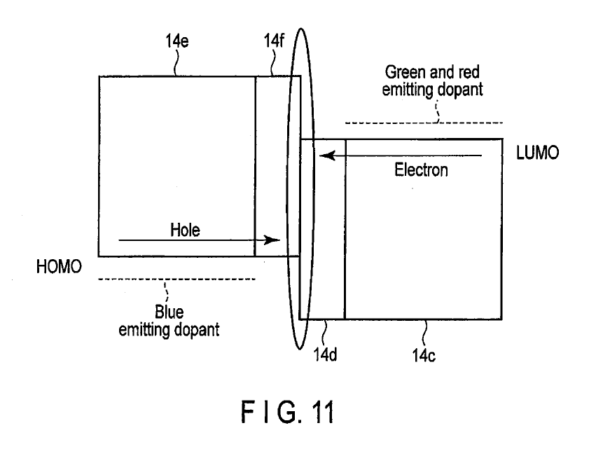

FIG. 11 is a view showing a third modification of an organic light-emitting diode according to an embodiment.

In the third modification, the blue emissive layer 14a includes the region 14e at the anode side which contains the hole transport host material and the blue emitting dopant and the region 14f at the cathode side which contains the hole transport host material and does not contain the emitting dopant. Further, the green and red emissive layer 14b includes the region 14c at the cathode side which contains the electron transport host material, the green phosphorescent dopant, and the red phosphorescent dopant and the region 14d at the anode side which contains the electron transport host material and does not contain the emitting dopant. The material included in each layer and the methods of producing each layer are as described in the first and second modifications.

The diode configurations as the first to third modifications allows energy deactivation associated with the contact of the blue fluorescent dopant with the green phosphorescent dopant and/or the red phosphorescent dopant to be prevented. Thus, the further improvement in the emission efficiency can be expected.

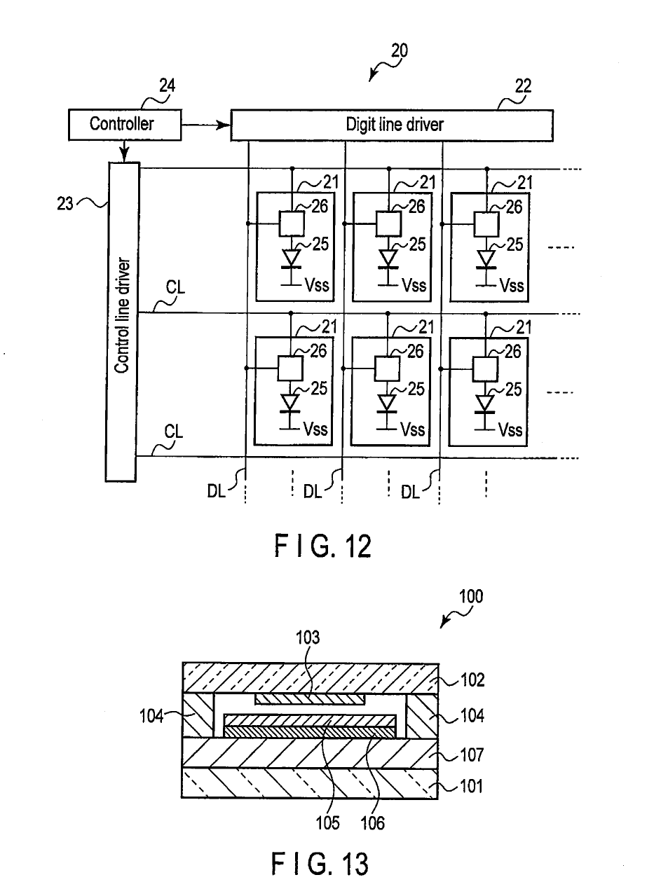

As an example of the application of the organic light-emitting diode described above, a display and an illuminating device are listed. FIG. 12 is a circuit diagram showing a display according to an embodiment.

A display 20 shown in FIG. 2 has a structure in which pixels 21 are arranged in circuits each provided with a lateral control line (CL) and vertical digit line (DL) which are arranged matrix-wise. The pixel 21 includes a light-emitting diode 25 and a thin-film transistor (TFT) 26 connected to the light-emitting diode 25. One terminal of the TFT 26 is connected to the control line and the other is connected to the digit line. The digit line is connected to a digit line driver 22. Further, the control line is connected to the control line driver 23. The digit line driver 22 and the control line driver 23 are controlled by a controller 24.

FIG. 13 is a cross-sectional view showing a lighting device according to an embodiment.

A lighting device 100 has a structure in which an anode 107, an organic light-emitting diode layer 106 and a cathode 105 are formed in this order on a glass substrate 101. A seal glass 102 is disposed so as to cover the cathode 105 and adhered using a UV adhesive 104. A drying agent 103 is disposed on the cathode 105 side of the seal glass 102.

### EXAMPLES

### Example 1

A transparent electrode with a thickness of 100 nm composed of indium tin oxide (ITO) was formed on a glass substrate by vacuum deposition and the resultant electrode was used as an anode. As a hole transport layer material, an aqueous solution of PEDOT:PSS [poly(3,4-ethylenedioxythiophene):polystyrene sulfonate] was used. The aqueous solution was applied to an anode by spin coating, followed by heating and drying at 200° C. for 5 minutes to from a hole transport layer with a thickness of 80 nm. As a blue emissive layer material, TCTA as a hole transport host material and DSA-Ph as a blue fluorescent dopant were used. These materials (at a weight ratio of 95:5 [TCTA:DSA-Ph]) were co-evaporated on the hole transport layer using a vacuum evaporator to form a blue emissive layer with a thickness of 40 nm. As a red emissive layer material, OXD-7 as an electron transport host material, TCTA as a hole transport material, and Ir(MDQ)₂(acac) as a red phosphorescent dopant were used. These materials (at a weight ratio of 30:60:10 (OXD-7:TCTA:Ir(MDQ)₂(acac)) were co-evaporated on the blue emissive layer using a vacuum evaporator to form a red emissive layer with a thickness of 40 nm. Thereafter, cesium fluoride was vacuum deposited on the red emissive layer to form electron injection and transport layers with a thickness of 1 nm. Further, aluminium was vacuum deposited on the electron injection and transport layer to form a cathode with a thickness of 50 nm.

The T1 energy of Ir(MDQ)₂ (acac) is 2.0 eV and the T1 energy of DSA-Ph is <2.0 eV.

### Test Example 1

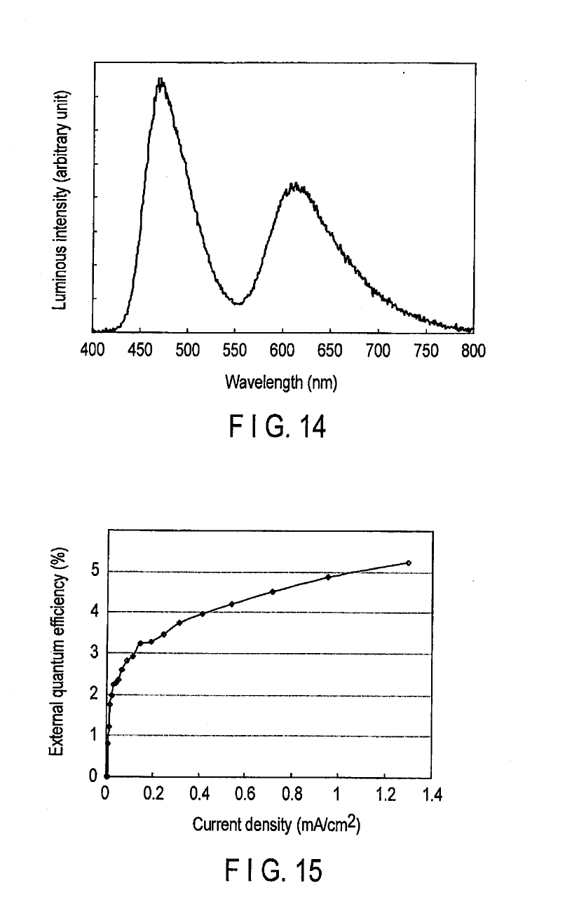

The electroluminescence spectrum and external quantum efficiency as to the diode fabricated in Example 1 were measured. FIG. 14 is a view showing the electroluminescence spectrum of an organic light-emitting diode according to Example 1. From FIG. 14, it was confirmed that the luminescence of both the blue fluorescence and red phosphorescence could be obtained. FIG. 15 is a view showing the external quantum efficiency of an organic light-emitting diode according to Example 1. From FIG. 15, it was confirmed that the organic light-emitting diode according to Example 1 exhibited high external quantum efficiency more than 5%, i.e., a theoretical threshold value of the external quantum efficiency of a fluorescent organic light-emitting diode.

From the test examples, it was confirmed that the organic light-emitting diode fabricated by using the blue fluorescent dopant having the T1 energy lower than that of the red phosphorescent dopant exhibited excellent emission properties.

Therefore, according to the embodiments or examples, the blue fluorescent dopant can be used regardless of the T1 energy and the white organic light-emitting diode capable of obtaining high emission efficiency can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic light-emitting diode comprising:
an anode and a cathode which are arranged apart from each other;
an emissive layer arranged between the anode and the cathode comprising a blue emissive layer located at the anode side and a green and red emissive layer located at the cathode side, the blue emissive layer containing a host material and a blue fluorescent dopant, and the green and red emissive layer containing a host material and a green phosphorescent dopant and/or a red phosphorescent dopant;
where the excited triplet energy of the blue fluorescent dopant is lower than at least one of the excited triplet energy of the green phosphorescent dopant and the red phosphorescent dopant, the excited triplet energy of the host material included in the blue emissive layer is higher than that of the host material contained in the green and red emissive layer, the energy level of HOMO of the host material contained in the blue emissive layer is shallower than that of HOMO of the host material contained in the green and red emissive layer, the energy level of LUMO of the host material contained in the blue emissive layer is shallower than that of LUMO of the host material contained in the green and red emissive layer, and excitons are generated at the interface between the blue emissive layer and the green and red emissive layer.

2. The organic light-emitting diode according to claim 1,
wherein the host material contained in the blue emissive layer is a hole transport host material and the host material contained in the green and red emissive layer is a bipolar host material or an electron transport host material.

3. The organic light-emitting diode according to claim 1,
wherein the exciton is an exciplex.

4. The organic light-emitting diode according to claim 2,
wherein the energy level of HOMO of the hole transport host material in the blue emissive layer is the same as or shallower than that of the blue fluorescent dopant, and the energy level of LUMO of the electron transport host material in the green and red emissive layer is the same as or deeper than that of the green phosphorescent dopant and the red phosphorescent dopant.

5. The organic light-emitting diode according to claim 4,
wherein the hole transport host material is N,N′-dicarbazolyl-3,5-benzene, di-[4-(N,N-ditolylamino)phenyl]cyclohexane or 4,4′,4″-tris(9-carbazolyl)-triphenylamine and the electron transport host material is 1,3-bis(2-(4-tertiary-buthylphenyl)-1,3,4-oxadiazol-5-yl)benzene or 4,4′-bis(9-dicarbazolyl)-2,2′-biphenyl.

6. The organic light-emitting diode according to claim 2,
wherein the green and red emissive layer further comprises a hole transport material.

7. A display comprising:
the organic light-emitting diode according to claim 1.

8. A lighting device comprising:
the organic light-emitting diode according to claim 1.
